(19) United States
(12) Patent Application Publication
(10) Pub. No.: US 2018/0254318 A1
(43) Pub. Date: Sep. 6, 2018

(54) GRAPHENE BASED IN-PLANE MICRO-SUPERCAPACITORS

(71) Applicant: William B Pohlman, III, Camp Verde, AZ (US)

(72) Inventor: William B Pohlman, III, Camp Verde, AZ (US)

(21) Appl. No.: 15/791,792

(22) Filed: Oct. 24, 2017

Related U.S. Application Data
(60) Provisional application No. 62/466,206, filed on Mar. 2, 2017.

(51) Int. Cl. H01L 49/02; H01L 23/522; H01L 23/532

(52) U.S. Cl. CPC H01L 28/75; H01G 11/36; H01L 23/53276; H01L 23/5223

(57) ABSTRACT

An integrated circuit with improved performance includes conventional integrated circuit layers including at least one integrated circuit power layer; an insulator material layer with a lattice structure deposited across the conventional integrated circuit layers; a first graphene layer deposited on the insulator material layer; a dielectric layer deposited on the first graphene layer; a second graphene layer deposited on the dielectric layer; a top passivation layer deposited on the second graphene layer; a first metallization post extending from the first graphene layer to the at least one integrated circuit power layer; and a second metallization post extending from the second graphene layer to the at least one integrated circuit power layer.

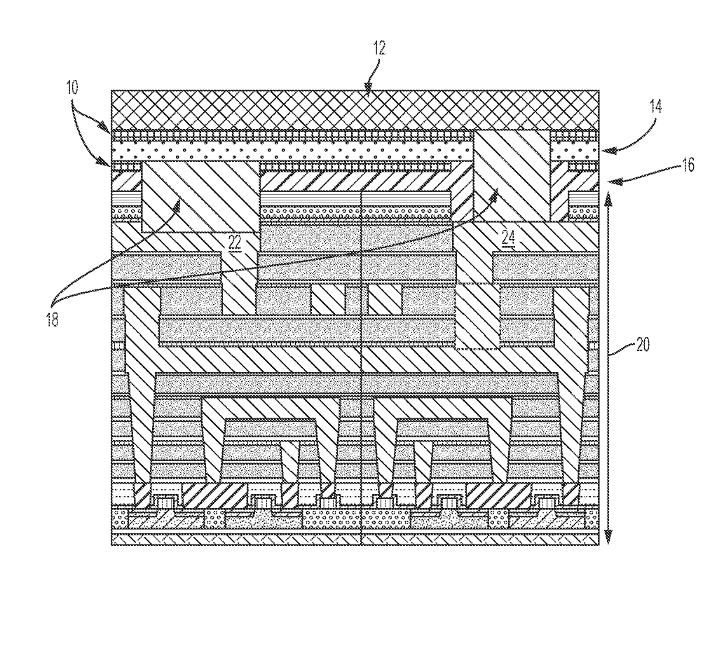

### RELATED APPLICATION

This application claims priority to provisional patent application U.S. Ser. No. 62/466,206 filed on Mar. 2, 2017, the entire contents of which is herein incorporated by reference.

### BACKGROUND

The embodiments herein relate generally to electrical circuitry, and more particularly, to a graphene based power distribution for high performance integrated circuits.

Conventional integrated circuits include aluminum or copper deposition for power distribution. However, current high-performance microprocessors running at high clock rates, such as those greater than 3 GHz, are prone to voltage drops and noise that can cause the integrated circuits to malfunction due to soft (recoverable) errors, particularly when sudden surges of power are needed for certain computations, like floating point operations. The lack of low source reactive impedance in power distribution at high frequencies thus limits the performance of today's microprocessors.

Moreover, the existing integrated circuits include a plurality of decoupling capacitors on the underside of the microprocessor package. These capacitors are designed to reduce noise on the power distribution within the processor by reducing the reactive source impedance at high frequency. However, these capacitors are too far from the power use itself, since there is reactive loop inductance and its resultant back EMF, which reduces their effectiveness, particularly at high clock rates. Thus, the capacitors limit the processor speed.

Therefore, what is needed is a power distribution with superior electron mobility and, thus, lower sheet resistance, allowing power to be distributed locally and evenly with low reactive impedance across an integrated circuit (IC), preventing voltage drops, noise and thermal hot spots allowing increasing clock rates and performance. Moreover, what is needed is a structure that allows for the elimination or reduction of the need for decoupling capacitors with high loop inductance on the underside of a microprocessor package.

### SUMMARY

Some embodiments of the present disclosure include an integrated circuit with improved performance includes conventional integrated circuit layers including at least one integrated circuit power layer; an insulator material layer with a compatible lattice structure deposited across the conventional integrated circuit layers; a first graphene layer deposited on the insulator material layer sharing the same crystallographic orientation; a dielectric layer deposited on the first graphene layer; a second graphene layer deposited on the dielectric layer forming a nanosheet monolayer heterostructure; a top passivation layer (typical of all integrated circuits) deposited on the second graphene layer; a first metallization post (or graphene nanotube) extending from the first graphene layer to the at least one integrated circuit power layer; and a second metallization post (or graphene nanotube) extending from the second graphene layer to the at least one integrated circuit power ground layer. The nanosheet heterostructure also adds to the radiation shielding of the passivation layer further reducing soft errors.

### BRIEF DESCRIPTION OF THE FIGURES

The detailed description of some embodiments of the invention is made below with reference to the accompanying FIGURE, wherein like numerals represent corresponding parts of the FIGURE.

FIGURE is a cross sectional view of one embodiment of the present disclosure.

### DETAILED DESCRIPTION OF CERTAIN EMBODIMENTS

In the following detailed description of the invention, numerous details, examples, and embodiments of the invention are described. However, it will be clear and apparent to one skilled in the art that the invention is not limited to the embodiments set forth and that the invention can be adapted for any of several applications.

The device of the present disclosure may be used as a power distribution on integrated circuits and may comprise the following elements. This list of possible constituent elements is intended to be exemplary only, and it is not intended that this list be used to limit the device of the present application to just these elements. Persons having ordinary skill in the art relevant to the present disclosure may understand there to be equivalent elements that may be substituted within the present disclosure without changing the essential function or operation of the device.
a. Integrated Circuit
b. Graphene Deposition Layer

The various elements of the device of the present disclosure may be related in the following exemplary fashion. It is not intended to limit the scope or nature of the relationships between the various elements and the following examples are presented as illustrative examples only.

By way of example, and referring to FIGURE, some embodiments of the present disclosure include an integrated circuit (IC), such as that for a microprocessor, with improved performance, wherein the integrated circuit comprises conventional integrated circuit layers 20 and at least one layer of graphene 10 deposited across the integrated circuit layers 20. The integrated circuit may also comprise metallization posts 18 that extend from the integrated circuit power layers 20 and intersect the at least one graphene layer 10 at a cross section to minimize contact resistance.

The graphene layer(s) 10 of the present disclosure may themselves be either monolayer of multi-bilateral depending on the conductivity desired. When bilateral layers of graphene 10 are used, interstitial doping may also be needed to improve conductivity vertically between graphene layers 10.

In a particular embodiment and as shown, for example, in FIGURE, a lattice structure compatible layer of insulator-like material, such as a hexagonal boron nitride (h-BN) graphene sublayer 16, may be deposited across the conventional IC layers 20, wherein the h-BN graphene sublayer 16 may promote lattice alignment making it easier to deposit high quality, defect free graphene. A first graphene layer 10 may be deposited on the h-BN graphene sublayer 16. A dielectric layer, such as an h-BN dielectric layer 14, may be deposited on the first graphene layer 10 as a capacitive dielectric, and a second graphene layer 10 may be deposited on the h-BN dielectric layer 14, completing a capacitive structure. Thus, the graphene layer(s) 10 may form decoupling capacitor plates. Lastly, a top passivation layer 12, such as a SiO₂ layer, may be deposited on the second graphene layer 10, as in typical integrated circuit manufacturing for chip protection. As shown in FIGURE, the IC may include a metallization post 18 that extends from each graphene layer 10 to the IC power and ground layers.

In some embodiments, the graphene may be deposited across the surface of the IC layers 20 in epitaxial deposited multi-layers by, for example, chemical vapor deposition (CVD). The graphene layer(s) 10 may eliminate the need for aluminum, copper, or other conventional power distribution networks. Thus, these conventional layers may be removed from the IC, allowing for denser designs.

In a particular embodiment, the device of the present disclosure may be made using the following steps. A planar layer of h-BN insulator 16 may be deposited onto a completed microprocessor semiconductor wafer prior to final passivation. A graphene monolayer 10 may be deposited via CVD onto the planar layer of h-BN insulator 16, wherein the graphene monolayer 10 may provide a first highly conductive plate of a super capacitor. The graphene h-BN layers may be patterned and etched to provide access to metal pads of the VSS ground layer. The material below the area of the VDD posts may also be removed. Aluminum or copper may be deposited to create conductive metallization posts 18 to the ground-layer. These posts 18 may intersect the cross section of graphene 10, which minimizes contact resistance. Any unnecessary metallization may be removed. Next, a layer of h-BN 14 is deposited on the graphene layer 10 to form the dielectric of the capacitor. The second plate of the capacitor may be formed with another layer of graphene 10, which may be deposited via CVD. The second layer of graphene 10 may be patterned and etched down to form access to the VDD voltage network as shown in FIGURE. Metallization (aluminum or copper) may be deposited to form the connection posts to VDD power network, which again connects to the top graphene layer 10 at the cross-section to minimize contact resistance, and excess metallization is removed. A final passivation layer, such as a SiO₂ layer 12 may be added, thus forming the final graphene on-chip high frequency decoupling supercapacitor.

While the above method is described as occurring before final passivation of the chip, the process could also be used after the final passivation with minor adjustments. Additionally, all depositions of chemical vapors (CVD) may be done at temperatures below that which would not affect the underlying semiconductor process. Moreover, a similar process without graphene using standard metallization technologies and commonly used dielectrics could also create an on-chip decoupling capacitance with lower quality and performance.

As a result of including graphene layers 10 on an IC, clock rates and, thus, performance may be increased. Graphene supercapacitors store and deliver energy electrochemically with high discharge rates. Their energy densities are vastly superior to conventional dielectric capacitors, by several orders of magnitude, which makes them ideal for decoupling capacitors, especially when located directly on the microprocessor chip with the minimum possible loop inductance. The capacitance may be increased by folding and additional graphene layers without degrading quality of electrical ESL performance, but at the cost of additional process complexity. Accordingly, the products may operate at lower voltages and, thus, lower power since accurate and precise power delivery enable low voltage operation. The significant noise reduction in the power network provided by the on-chip decoupling technology may also allow microprocessors to run reliably at lower voltages, thus reducing power consumption and/or enabling higher over-clocking rates for additional performance. As microprocessor semiconductor technologies advance to higher density lithography (e.g., less than 10 nm), this high quality on-chip decoupling technology may, in fact, become an enabling technology as these advanced processes with their low threshold high leakage transistors require low voltage operation. Advanced processes also typically lead to higher MOS transistor source-drain leakage creating voltage and ground offsets that further reduce logic noise margins.

Persons of ordinary skill in the art may appreciate that numerous design configurations may be possible to enjoy the functional benefits of the inventive systems. Thus, given the wide variety of configurations and arrangements of embodiments of the present invention the scope of the invention is reflected by the breadth of the claims below rather than narrowed by the embodiments described above.

1. An integrated circuit with improved performance, the integrated circuit comprising:
conventional integrated circuit layers;
an insulator material layer deposited across the conventional integrated circuit layers, the insulator material layer comprising a hexagonal boron nitride (h-BN) graphene sublayer; and
at least one layer of graphene deposited across the insulator material layer,
wherein the insulator material layer and the at least one layer of graphene have the same crystallographic orientation.

2. The integrated circuit of claim 1, wherein:
the conventional integrated circuit layers include an integrated circuit power layer; and
a metallization post extends from the integrated circuit power layer to intersect the at least one graphene layer.

3. The integrated circuit of claim 1, wherein the at least one graphene layer is selected from the group consisting of a monolayer and a multi-bilateral layer.

4. An integrated circuit with improved performance, the integrated circuit comprising:
conventional integrated circuit layers including at least one integrated circuit power layer;
an insulator material layer with a lattice structure deposited across the conventional integrated circuit layers, the insulator material layer comprising a hexagonal boron nitride (h-BN) graphene sublayer;
a first graphene layer deposited on the insulator material layer;
a dielectric layer deposited on the first graphene layer, the dielectric layer comprising hexagonal boron nitride (h-BN) dielectric layer;
a second graphene layer deposited on the dielectric layer;
a top passivation layer deposited on the second graphene layer;
a first metallization post extending from the first graphene layer to the at least one integrated circuit power layer; and
a second metallization post extending from the second graphene layer to the at least one integrated circuit power layer,
wherein the insulator material layer and the first graphene layer have the same crystallographic orientation.

5. (canceled)

6. (canceled)

7. The integrated circuit of claim 4, wherein the top passivation layer comprises a SiO₂ layer.

8. An integrated circuit, comprising:
a first substrate layer;
a second substrate layer;
an insulation layer positioned over the first substrate layer;
a graphene supercapacitor positioned over the first substrate layer, wherein the insulator layer and at least one layer of the graphene supercapacitor have a same crystallographic orientation; and
a conductive path connecting the graphene supercapacitor, through the insulation layer, to the second substrate layer.
